(19) United States
(12) Patent Application Publication
(10) Pub. No.: US 2020/0137426 A1
(43) Pub. Date: Apr. 30, 2020

(54) MATCHING METHOD OF SHARED DISPLAY MODULE

(71) Applicant: National Sun Yat-sen University, Kaohsiung (TW)

(72) Inventors: Tsung-Hsien LIN, Kaohsiung (TW); Cheng-Chang Li, Kaohsiiung (TW); Heng-Yi Tseng, Kaohsiung (TW); Hung-Chang Jau, Kaohsiung (TW)

(21) Appl. No.: 16/221,519

(22) Filed: Dec. 16, 2018

(30) Foreign Application Priority Data
Oct. 31, 2018 (TW) 107138658

(51) Int. Cl. H04N 21/238; H01L 51/52; G02F 1/13; G03B 21/62; H04H 60/15

(52) U.S. Cl. CPC H04N 21/238; H01L 51/52; G02F 2001/133627; G03B 21/62; H04H 60/15; G02F 1/1306

(57) ABSTRACT

A matching method of a shared display module is provided and has steps of: receiving, by a mediation platform, a service requirement specification, wherein the service requirement specification has a lease time zone of at least one display module disposed an a building exterior wall; comparing, by the mediation platform, the service requirement specification with at least one service providing specification of a plurality of service providers in the mediation platform; and transmitting, by the mediation platform, at least one compared service providing specification matching with the service requirement specification to a user end of the service requirement specification. The matching method matches a leasable time zone of the display module on the building exterior wall by the mediation platform, so that the display module displays an image or a video demanded by the user end.

### CROSS REFERENCE TO RELATED APPLICATION

This application claims priority to Taiwan Patent Application No. 107138658, filed on Oct. 31, 2018, which is incorporated herein by reference in its entirety.

### FIELD OF DISCLOSURE

The present disclosure relates to a matching method, and more particularly to a matching method of a shared display module.

### BACKGROUND OF DISCLOSURE

In a current industrial and commercial society, promotion and sales of products and/or services are the most important business activities of general corporate companies, Companies are committed to the promotion of their products and/or services to achieve their corporate development and sustainable business. To achieve this, the promotion and sales of products, and/or services are mainly achieved through advertising. Therefore, through dissemination of advertising from a media, consumers are able to know characteristics and advantages of these products and/or services, and a way to obtain them from a channel, so as to develop and expand the channel of these products and/or services. However, conventional advertising channels are still insufficient to meet existing needs.

As a result, it is necessary to provide a matching method of a shared display module to solve the problems existing in the conventional technologies, as described above.

### SUMMARY OF DISCLOSURE

An object of the present disclosure is to provide a matching method of a shared display module, which is to match a leasable time zone of the display module on a building exterior wall by the mediation platform, so that the display module displays an image or a video demanded by the user end.

To achieve the above object the present disclosure provides a matching method of a shared display module, which comprises steps of: receiving, by a mediation platform, a service requirement specification, wherein the service requirement specification includes a lease time zone of at least one display module disposed on a building exterior wall; comparing, by the mediation platform, the service requirement specification with at least one service providing specification of a plurality of service providers in the mediation platform; and transmitting, by the mediation platform, at least one compared providing specification matching with the service requirement specification to a user end of the service requirement specification.

In an embodiment of the present disclosure, the at least one display module includes at least one of a transparent liquid crystal display, a transparent organic light emitting diode display, a switchable rear projection liquid crystal screen, and an electrochromic glass.

In an embodiment of the present disclosure, after transmitting the at least one compared providing specification to the user end of the service requirement specification, the matching method further comprises: receiving, by the mediation platform, a determining step from the user end, wherein the determining step comprises selecting at least one of the service providers.

In an embodiment of the present disclosure, after the determining step, the matching method further comprises a step of: transmitting, by the mediation platform, a matching success message to the at least one of the service providers.

In an embodiment of the present disclosure, in the determining step, the matching method further comprises a step of: confirming, by the mediation platform, a payment message from the user end or at least one of the service providers.

In art embodiment of the present disclosure, after the determining step, the matching method further comprises: providing, by the mediation platform, a display permission of the at least one display module in the lease time zone to the user end.

In an embodiment of the present disclosure, the display permission comprises includes displaying at least one of an image, a video, a text, and a sentence.

In an embodiment of the present disclosure, the service requirement specification further includes: at least one of a rental location requirement, a rental fee requirement, and a construction fee requirement of the at least one display module.

In an embodiment of the present disclosure, the at least one service providing specification further includes: at least one of a lease location providing, a lease fee providing, and a construction fee providing of the at least one display module.

In an embodiment of the present disclosure, the user end includes: at least one of a desktop computer, a notebook computer, a tablet computer, and a smart phone.

### DESCRIPTION OF DRAWINGS

FIG. 1 is a flowchart of a matching method of a shared display module according to an embodiment of the present disclosure.

FIG. 2 is a schematic block diagram of a mediation platform according to an embodiment of the present disclosure.

### DETAILED DESCRIPTION OF PREFERRED EMBODIMENTS

The structure and the technical means adopted by the present disclosure to achieve the above and other objects can be best understood by referring to the following detailed description of the preferred embodiments and the accompanying drawings. Furthermore, directional terms described by the present disclosure, such as upper, lower, front, back, left, right, inner, outer, side, longitudinal/vertical, transverse/horizontal, and etc., are only directions by referring to the accompanying drawings, and thus the used directional terms are used to describe and understand the present disclosure, but the present disclosure is not limited thereto.

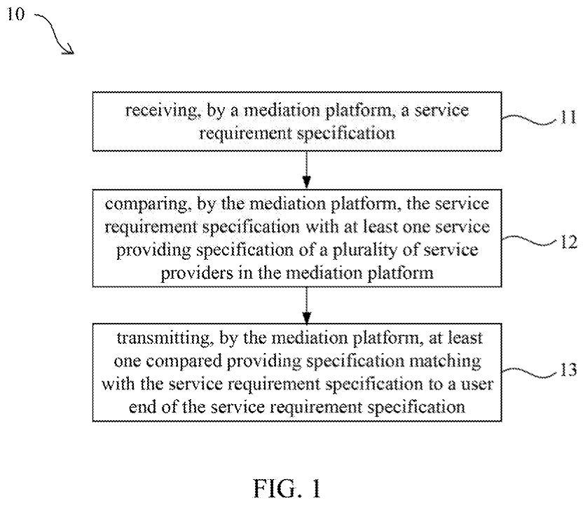

Referring to FIG. 1, a matching method 10 of a shared display module in an embodiment of the present disclosure mainly comprises steps 11-13 of receiving, by a mediation platform, a service requirement specification, wherein the service requirement specification includes a lease time zone of at least one display module disposed on a building exterior wall (step 11); comparing, by the mediation platform, the service requirement specification with at least one service providing specification of a plurality of service providers in the mediation platform (step 12); and transmitting, by the mediation platform, at least one compared providing specification matching with the service requirement specification to a user end of the service requirement specification (step 13). Details of the implementation and principles of the above-described steps of embodiments will be described in detail below.

The matching method 10 of the shared display module according to an embodiment of the present disclosure has a step 1 of receiving, by a mediation platform, a service requirement specification, wherein the service requirement specification includes a lease time zone of at least one display module disposed on a building exterior wall. In the step 11, the at least one display module includes such as at least one of a transparent liquid crystal display, a transparent organic light emitting diode display, a switchable rear projection liquid crystal screen, and an electrochromic glass. In one embodiment, the service requirement specification further includes: at least one of a rental location requirement, a rental fee requirement, and a construction fee requirement of the at least one display module.

The matching method 10 of the shared display module according to an embodiment of the present disclosure has a step 12 of comparing, by the mediation platform, the service requirement specification with at least one service providing specification of a plurality of service providers in the mediation platform. In the step 12, the at least one service providing specification further includes: at least one of a lease location providing, a lease fee providing, and a construction fee providing of the at least one display module.

The matching method 10 of the shared display module according to an embodiment of the present disclosure has a step 13 of transmitting, by the mediation platform, at least one compared providing specification matching with the service requirement specification to a user end of the service requirement specification. In the step 13, the user end includes such as at least one of a desktop computer, a notebook computer, a tablet computer, and a smart phone.

In an embodiment, after transmitting the at least one compared providing specification to the user end of the service requirement specification, the matching method 10 further comprises receiving, by the mediation platform, a determining step from the user end, wherein the determining step comprises selecting at least one of the service providers.

In an embodiment, after the determining step, the matching method 10 further comprises a step of: transmitting, by the mediation platform, a matching success message to the at least one of the service providers.

In an embodiments in the determining step, the matching method further comprises a step of: confirming, by the mediation platform, a payment message from the user end or at least one of the service providers.

In an embodiment, after the determining step, the matching method 10 further comprises providing, by the mediation platform, a display permission of the at least one display module in the lease time zone to the user end. In another embodiment, the display permission comprises includes displaying at least one of an image, a video, a text, and a sentence.

Several embodiments will be described to illustrate various application scenarios or aspects of a matching method 10 of a shared display module according to embodiments of the present disclosure. However, it is noted that various application scenarios or aspects described later are not used as any limitation of an embodiment of the present disclosure.

Application Scenario 1

In the case where a user wants to rent out at least one display module on a building exterior wall, the user can input service request specifications (for example, a rental time is between 18:00 and 24:00 daily, a rental request fee is 10 dollars per hour, and a rental requirement location is at place X and road Y. into a search function column of the mediation platform, so as to search for whether other users want to rent the display module of the building exterior wall. If there is at least one eligible service provider in the mediation platform (e.g., in a database of the media platform), the mediation platform passes at least one compared service providing specifications matching with the service requirement specification to the user (or the user end).

Next, the user can decide whether to select at least one of the service providers as an object of successful mediation. If yes, the user can send a confirmation message to the mediation platform, for example, by using the user end, so that the mediation platform delivers a matching success message to the at least one of the selected service providers. If not, the user can modify a content of the service request specification to find service providers who may succeed in matching.

In another aspect, the service requirement specification provided by the user can also be used as a service providing specification. In other words, in addition to actively matching the service providers already existing in the database of the mediation platform, the user can also act as one of the service providers for the passive matching. For example, the user can establish at least one service providing specification (for example, a lease time zone is between 18:00 and 24:00 daily, a lease fee providing is 10 yuan per hour, and the lease location providing is place X and road Y) for active matching by other users.

In the above application scenario, the mediation platform can serve as a payment confirmation end. For example, in the application scenario 1, if the user end wants to rent out at least one display module on the exterior wall of the building to the at least one of the selected service providers, the at least one of the selected service providers can pay the fees directly or indirectly to the user via an existing known payment delivery method. The mediation platform notifies a payment message to the user after confirming that the user has received the payment in the above manner.

In an embodiment, the mediation platform may charge an appropriate fee based on a set condition. For example, a certain percentage of the fee is charged in the process of confirming the payment message; or a certain percentage of the fee is charged when the above-mentioned at least one service providing specification is established; or the mediation platform is charged using a membership system.

It is noted that, if the user wants to rent at least one display module on a budding exterior wall, it can be performed, in a manner similar to the above, and therefore will not be described again.

Application Scenario 2

If a user (or a service provider) does not have a display module, the user (or the service provider) may also include a construction fee requirement (or a construction fee providing) in a service requirement specification (or in a service providing specification). In the application scenario 2, if the user (or the service provider) can not disposes the display module, the display module can be implemented by a third-party manufacturer (for example, a manufacturer of the display module). In an embodiment, the third-party manufacturer can dispose a suitable display module according to a condition of an exterior wall of a building or an appearance required according to a renter, for example, an ordinary glass of the exterior wall of the building can be replaced by one or more of electrochromic glasses; or a transparent liquid crystal display, a transparent organic light emitting diode display, or a switchable rear projection liquid crystal screen is mounted on the ordinary glass. In another aspect, the display module may also be a combination of the above-exemplified embodiments (i.e., having multiple display modules) such that a portion of the display modules are transparent, and another portion of the display modules are opaque (or displaying images, videos, texts, or sentences), so as to form an arrangement of words or patterns.

Application Scenario 3

A matching method of a shared display module in an embodiment of the present disclosure is not limited to advertising purposes. For example, if a user wants to share a picture or a video on a user terminal (such as a smart phone) for others to watch, the display module near the user can be rented out through the mediation platform. At least one advantage of this method is that, since an outer wall of a general building has a large surface area, the display module can also have a large display area, which is convenient for multiple people to watch, tore specifically, through the matching method of the shared display module, the display module of the building exterior wall actually becomes a portable-free large-screen device. For the user, the user can only carry a networkabie electronic device which can be communicated with the mediation platform through the network, thereby completing the matching method of the shared display module in the embodiment of the present disclosure.

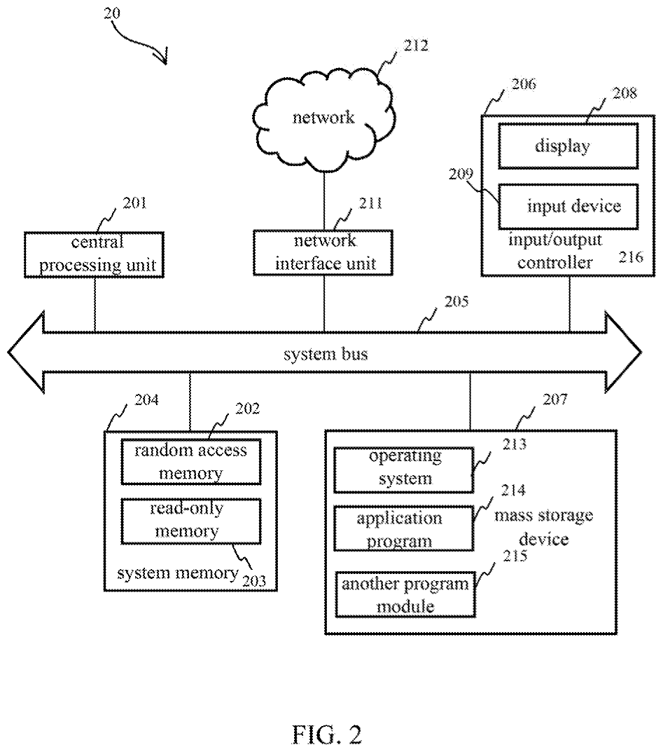

In one embodiment, the mediation platform can be a server which includes hardware and software of a computer. For example, referring to FIG. 2, a mediation platform 20 includes a central processing unit (CPU) 201, a system memory 204 that includes a random access memory (RAM) 202 and a read-only memory (ROM) 203, and a system bus 205 that connects the system memory 204 and the central processing unit 201. The mediation platform 20 further includes a basic input/output system (I/O system) 206 that illustrates components in a computer to transmit information and a mass storage device 207 (which can be, used as a database, and can be used to store software) that is configured to store an operating system 213, an application program 214, and another program module 215.

The basic I/O system 206 includes a display 208 that is configured to display information and an input device 209 such as a mouse or a keyboard that is configured for a user to input information. Both the display 208 and the input device 209 are connected to the central processing unit 201 by using an input/output controller 216 that is connected to the system bus 205. The basic I/O system 206 may further include the input/output controller 216, so as to receive and process inputs from multiple other devices such as the keyboard, the mouse, and an electronic stylus. Similarly, the input/output controller 216 further provides an output to a display screen, a printer, or an output device of another type.

The mass storage device 207 is connected to the central processing unit 201 by using a mass storage controller (not shown in the figure) that is connected to the system bus 205.

The mass storage device 207 and a computer readable medium associated with the mass storage device 207 provide non-volatile storage for the mediation platform 20. That is, the mass storage device 207 may include a computer readable medium (not shown in the figure) such as a hard disk or a CD-ROM drive.

Without loss of generality, the computer readable medium may include a computer storage medium and a communications medium. The computer storage medium includes a volatile, non-volatile, movable, or unmovable medium that is implemented by using any method or technology for storing information such as a computer readable instruction, a data structure, a program module, or other data. The computer storage medium includes a RAM, a ROM, an EPROM, an EEPROM, a flash memory, another solid-state storage medium, a CD-ROM, a DVD, another optical storage medium, a cassette, a magnetic tape, a magnetic disk, or anther magnetic storage device. Certainly, a person skilled in the art may learn that the computer storage medium is not limited to the foregoing types. The foregoing system memory 204 and mass storage device 207 may be collectively referred to as a memory.

According to embodiments of the present disclosure, the mediation platform 20 may also run on a remote computer that is connected to a network by using a network such as the Internet. That is, the mediation platform 20 may be connected to a network 212 by using a network interface unit 211 that is connected to the system bus 205, or the mediation platform 20 may also be connected to a network of another type or a remote computer system (not shown in the figure) by using the network interface unit 211.

In some embodiments, the mediation platform 20 receives a service requirement specification (provided by a user end) via the network interface unit 211 by using the network 212. Then, the central processing unit (CPU) 201 of the mediation platform 20 compares the service requirement specification with at least one service providing specification (existed in the mass storage device 207). Thereafter, transmitting at least one compared providing specification matching with the service requirement specification to the user end via the network interface unit 211 by using the network 212.

From above, an embodiment of the present disclosure provides a matching method of a shared display module, which is to match a leasable time zone of the display module on a building exterior wall by the mediation platform, so that the display module displays an image or a video demanded by the user end. In another aspect, since an owner of the external wall of the building can set an idle rentable period, a using method of the external wall of the building can be improved. In addition, since a display status of the display module can be changed by controlling the display module so that the status of the display module becomes light-transmitting for transparent), a light transmittance effect (or the transparent effect) of the ordinary glass on the external wall of the building is not affected during a non-lease period of the display module.

The present disclosure has been described with a preferred embodiment thereof and it is understood that many changes and modifications to the described embodiment can be carried out without departing from the scope sand the spirit of the disclosure that is intended to be limited only by the appended claims.

1. A matching method of a shared display module, comprising steps of:
receiving, by a mediation platform, a service requirement specification, wherein the service requirement specification includes a lease time zone of at least one display module disposed on a building exterior wall;
comparing, by the mediation platform, the service requirement specification with at least one service providing specification of a plurality of service providers in the mediation platform; and
transmitting, by the mediation platform, at least one compared providing specification matching with the service requirement specification to a user end of the service requirement specification.

2. The matching method of the shared display module according to claim 1, wherein the at least one display module includes at least one of a transparent liquid crystal display, a transparent organic light emitting diode display, a switchable rear projection liquid crystal screen, and an electrochromic glass.

3. The matching method of the shared display module according to claim 1, wherein after transmitting the at least one compared providing specification to the user end of the service requirement specification, the matching method further comprises: receiving, by the mediation platform, a determining step from the user end, wherein the determining step comprises selecting at least one of the service providers.

4. The matching method of the shared display module according to claim 1, wherein after the determining step, the matching method further comprises a step of: transmitting, by the mediation platform, a matching success message to the at least one of the service providers.

5. The matching method of the shared display module according to claim 3, wherein in the determining step, the matching method further comprises a step of: confirming, by the mediation platform, a payment message from the user end or at least one of the service providers.

6. The matching method of the shared display module according to claim 3, wherein after the determining step, the hatching method further comprises: providing, by the mediation platform, a display permission of the at least one display module in the lease time zone to the user end.

7. The matching method of the shared display module according to claim 6, wherein the display permission comprises includes displaying at least one of an image, a video, a text, and a sentence.

8. The matching method of the shared display module according to claim 1, wherein the service requirement specification further includes: at least one of a rental location requirement, a rental fee requirement, and a construction fee requirement of the at least one display module.

9. The matching method of the shared display module according to claim 1, wherein the at least one service providing specification further includes: at least one of a lease location providing, a lease fee providing, and a construction fee providing of the at least one display module.

10. The matching method of the shared display module according to claim 1, wherein the user end includes: at least one of a desktop computer, a notebook computer, a tablet computer, and a smart phone.
